(19) United States
(12) Patent Application Publication
(10) Pub. No.: US 2012/0018718 A1
(43) Pub. Date: Jan. 26, 2012

(54) Self-aligned top-gate thin film transistors and method for fabricating same

(75) Inventors: Hsiao-Wen Zan, Hsinchu (TW); Wei-Tsung Chen, Hsinchu (TW); Cheng-Wei Chou, Hsinchu City (TW); Chuang-Chuang Tsai, Hsinchu City (TW)

(73) Assignee: National Chiao Tung University, Hsuinchu City (TW)

(21) Appl. No.: 12/927,835

(22) Filed: Nov. 26, 2010

(30) Foreign Application Priority Data
Jul. 21, 2010 (TW) 99123917

(51) Int. Cl. H01L 29/12; H01L 21/04

(52) U.S. Cl. 257/43; 438/104; 257/E21.04; 257/E29.068

(57) ABSTRACT

A self-aligned top-gate thin film transistor and a fabrication method thereof. The method includes preparing a substrate having sequentially formed thereon an oxide semiconductor layer, a dielectric layer, and a metallic layer, wherein the oxide semiconductor layer includes first and second connecting regions that are not covered by the dielectric layer and the metallic layer thereon respectively, the first and second connecting regions having a property of a conductor after undergone a heating process or an ultraviolet irradiation; and a source electrode and a drain electrode formed on the substrate and connected to the first and second connecting regions, respectively. Therefore, the contact resistance of the first and second connecting regions can be reduced without the process of ion dopants as required by prior art techniques, thereby simplifying the manufacturing process. Also, the source electrode and the drain electrode can be exactly relocated and further increase performance of the device.

### BACKGROUND OF THE INVENTION

1. Field of the Invention

The present invention relates to thin film transistors, and more particularly, to a self-aligned top-gate thin film transistor and a method for fabricating the same.

2. Description of Related Art

Thin film transistors have been widely used in electronic products, for example, driver and switching devices of pixels of liquid crystal display (LCD) and active load devices in static random access memory (SRAM). For LCD applications, in order to meet the limitation of low-temperature and the requirements of large area in LCD process, top-gate polysilicon layer thin film transistors have recently been used as a main component for driving integrated circuits. Among various types of top-gate thin film transistor structures, since self-aligned coplanar thin film transistors are simple in process and lower in mask cost, they have been used most widely.

FIGS. 2A and 2B are schematic cross-sectional views showing the steps of fabricating a conventional top-gate thin film transistor 2. Firstly, as shown in FIG. 2A, a substrate 20, which can be an insulating transparent substrate such as glass substrate, is provided. A surface of the substrate 20 has a semiconductor layer 22 such as polysilicon layer formed thereon and a gate insulating layer 24 completely covering the semiconductor layer 22. In the conventional fabrication method, a first mask process is performed to form a patterned photoresist layer 26 on the gate insulating layer 24. Then, using the patterned photoresist layer 26 as a mask, a high-dopant-concentration implantation 27 is carried out to form a plurality of N⁺ doped regions 28 in the semiconductor layer 22 such as polysilicon layer under the periphery of the patterned photoresist layer 26. The N⁺ doped regions 28 are formed to act as source/drain regions.

Moreover, as shown in FIG. 2B, after the patterned photoresist layer 26 is removed, a second mask process is carried out to form a patterned gate layer 30 on the gate insulating layer 24. The patterned gate layer 30 only covers a portion of undoped region of the semiconductor layer 22 such as polysilicon layer and defines a pattern of a doping structure, to be formed in the semiconductor layer 22. Thereafter; using the gate layer 30 as a mask, a low-dopant-concentration implantation 31 is carried out to form an N⁻ doped region 32 in the undoped region of the semiconductor layer 22 under the periphery of the gate layer 30. The region of the semiconductor layer 22 covered by the gate layer 30 behaves as a channel.

However, when the material of active layer is replaced by a transparent oxide semiconductor and metals are used as source and drain electrodes, the contact resistance can not be reduced due to the omission of applying the ion implantation process. Therefore, a self-aligned coplanar thin film transistor is difficult to obtain.

Park et al. disclose a self-aligned top-gate thin film transistor in the paper of Applied physics letters 93, 053501 (2008). However, this self-aligned top-gate thin film transistor is produced by an argon plasma process with a high temperature condition in order to decrease the contact resistance between source/drain electrodes and an active layer. Since the plasma process has no directions and is carried out under high temperature condition, the technology development and the applicability of fabrication process of products are limited. In addition, FIG. 3 is a schematic cross-sectional view showing a conventional self-aligned top-gate thin film transistor 3. The self-aligned top-gate thin film transistor 3 includes an insulating layer 33 covering source/drain regions 35 and 36; a plurality of electrical connecting plugs 37 connecting the source/drain regions 35 and 36; and source/drain electrodes 38 and 39 formed on a top surface of the insulating layer 33. The process of fabricating the self-aligned top-gate thin film transistor 3, when compared with the process of fabricating the top-gate thin film transistor 2, is more complex.

Therefore, it is a necessary to develop a novel thin film transistor process which can simplify manufacturing steps and improve the performance of the devices by decreasing contact resistance.

### SUMMARY OF THE INVENTION

In light of the drawbacks of the aforementioned prior arts, the present invention provides a self-aligned top-gate thin film transistor and fabrication method thereof that can reduce the contact resistance without the process of ion dopants as required by prior art techniques, and simplify the manufacturing process.

Another objective of the present invention is to provide a fabrication method for forming a self-aligned top-gate thin film transistor, comprising the following steps: preparing a substrate having sequentially formed thereon an oxide semiconductor layer, a dielectric layer, and a metallic layer, wherein the oxide semiconductor layer is larger in area than the dielectric layer and the metallic layer, and is defined with a first and a second connecting regions that are not covered by the dielectric layer and the metallic layer; performing a heating process or an ultraviolet irradiation to the first connecting region and the second connecting region, with the metallic layer as a mask, allowing the first and second connecting regions to have a property of a conductor; and forming a source electrode and a drain electrode on the substrate and electrically connecting the source electrode and the drain electrode to the first and second connecting regions, respectively. In the aforesaid fabrication method, the contact resistance of the first and second connecting regions can be reduced by irradiating an ultraviolet light or a laser beam on the first and second connecting regions of the oxide semiconductor layer.

According to the aforesaid fabrication method, the present invention further provides a self-aligned top-gate thin film transistor, which comprises: a substrate; an oxide semiconductor layer formed on the substrate; a dielectric layer formed on the oxide semiconductor layer, allowing the oxide semiconductor layer to be sandwiched between the substrate and the dielectric layer; a metal layer formed on the dielectric layer, allowing the dielectric layer to be sandwiched between the oxide semiconductor layer and the metal layer, wherein the oxide semiconductor layer is larger in area than the dielectric layer and the metallic layer, and is defined with a first connecting region and a second connecting region that are not covered by the dielectric layer and the metallic layer, the oxide semiconductor layer of the first connecting region and the second connecting region having a property of a conductor; a source electrode formed on the substrate and electrically connected to the first connecting region; and a drain electrode formed on the substrate and electrically connected to the second connecting region.

In the aforesaid self-aligned top-gate thin film transistor and method for fabricating the same, the oxide semiconductor layer is made of at least a material selected from the group consisting of indium oxide, zinc oxide, gallium oxide, tin oxide and magnesium oxide. In addition, since the heating process or the irradiation is performed while using the metallic layer as a mask, the oxide semiconductor layer of the first connecting region and the second connecting region can directly have the property of a conductor. Also, a source electrode and a drain electrode can be formed by a simple conventional thin film deposition process, and the source electrode and the drain electrode can cover the first connecting region and the second connecting region, respectively, due to the utilization of the metallic layer as a mask.

### BRIEF DESCRIPTION OF THE DRAWINGS

FIG. 1A is a schematic cross-sectional view of a substrate having sequentially formed thereon an oxide semiconductor layer, a dielectric layer, and a metallic layer according to an embodiment of the present invention;

FIG. 1B is a schematic cross-sectional view showing a process for making a portion of an oxide semiconductor layer having the property of a conductor according to an embodiment of the present invention;

FIG. 1C shows a current-voltage characteristic diagram of an oxide semiconductor layer having the property of a conductor which is formed by irradiating an UV light on the oxide semiconductor layer according to an embodiment of the present invention;

FIG. 1D shows a current-voltage characteristic diagram of an oxide semiconductor layer having the property of conductor which is formed by irradiating a laser beam on the oxide semiconductor layer according to an embodiment of the present invention;

FIG. 1E is a schematic cross-sectional view of a self-aligned top-gate thin film transistor according to an embodiment of the present invention;

FIGS. 2A and 2B are schematic cross-sectional views showing the steps for fabricating a conventional top-gate thin film transistor; and

FIG. 3 is a schematic cross-sectional view of a conventional self-aligned top-gate thin film transistor.

### DETAILED DESCRIPTION OF THE PREFERRED EMBODIMENTS

The detailed description of the present invention is illustrated by the following specific examples. Persons skilled in the art can conceive the other advantages and effects of the present invention based on the disclosure contained in the specification of the present invention.

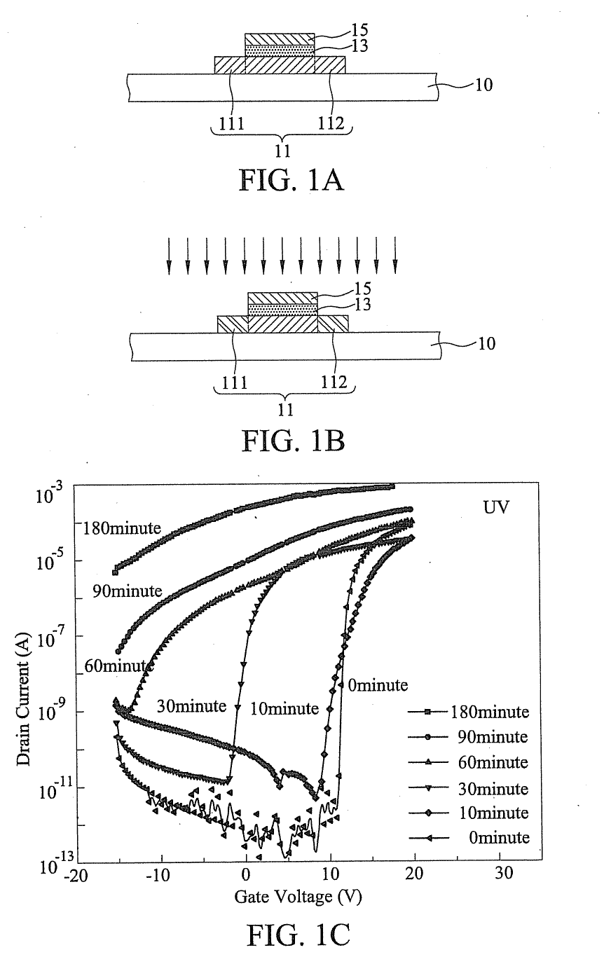

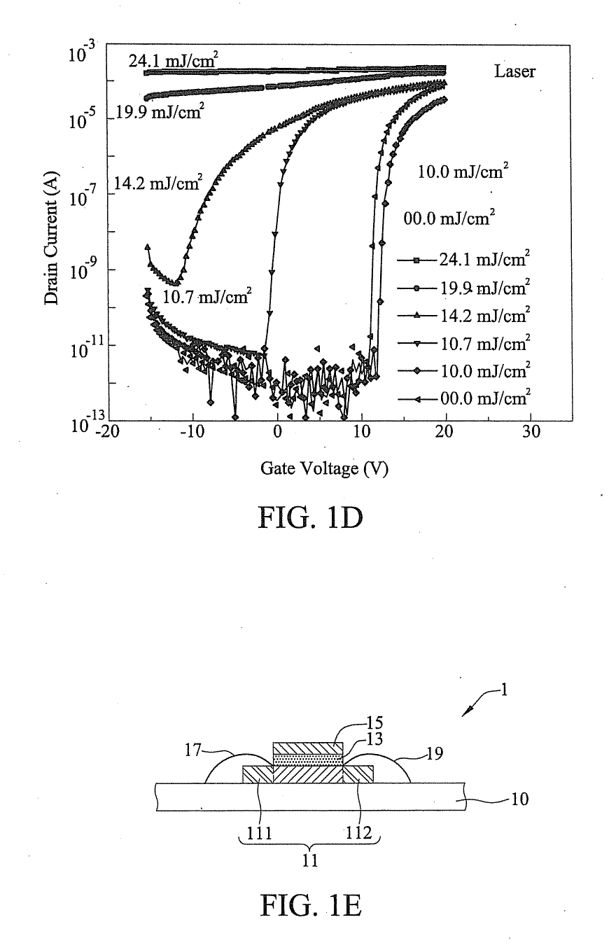

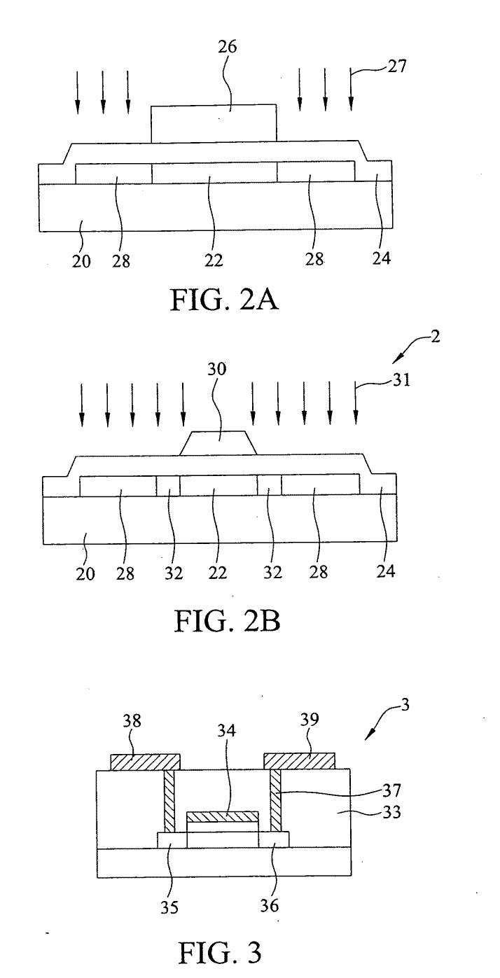

FIGS. 1A and 1B are schematic cross-sectional views showing the steps for fabricating a self-aligned top-gate thin film transistor according to an embodiment of the present invention.

Referring to FIG. 1A, a substrate 10 having sequentially formed thereon an oxide semiconductor layer 11, a dielectric layer 13, and a metallic layer 15 is provided. Therein, the area of the oxide semiconductor layer 11 is larger than the area of the dielectric layer 13 and the area of the metallic layer 15. The oxide semiconductor layer 11 is defined with a first connecting region 111 and a second connecting region 112 that are not covered by the dielectric layer 13 and the metallic layer 15. The oxide semiconductor layer 11 is usually formed on the substrate 10 by, for example, sputtering or conventional deposition techniques. The oxide semiconductor layer 11 is made of at least a material selected from the group consisting of indium oxide, zinc oxide, gallium oxide, tin oxide and magnesium oxide. Specifically, the oxide semiconductor layer 11 can be made of one of the materials in the aforesaid group as a base material or a major component of the oxide semiconductor layer 11, or two or more of the materials in the aforesaid group as a base material of the oxide semiconductor layer 11. Next, a photolithographic process is used to pattern out a region on the oxide semiconductor layer 11 for allowing a dielectric layer 13 to be formed therein. Then, the dielectric layer 13 is deposited on the oxide semiconductor layer 11, for example, by plasma-enhanced chemical vapor deposition. Finally, a metallic layer 15 is formed on the dielectric layer 13 as a gate electrode. The dielectric layer 13 can be made of silicon oxide or a material containing silicon oxide such as a material including silicon oxide and silicon nitride.

The dielectric layer 13 and the metallic layer 15 only cover a portion of the oxide semiconductor layer 11, such that the oxide semiconductor layer 11 has a first connecting region 111 and a second connecting region 112 that are not covered by the dielectric layer 13 and the metallic layer 15.

Again referring to FIG. 1B, using the metallic layer 15 as a mask, a heating process or an ultraviolet irradiation is performed to the first connecting region 111 and the second connecting region 112. Therefore, the oxide semiconductor layer 11 of the first connecting region 111 and the second connecting region 112 has the property of conductor. Typically, a wavelength of the irradiated ultraviolet is less than 400 nm. In one embodiment of the present invention, as shown in FIG. 1C, the first connecting region 111 and the second connecting region 112 have been irradiated for 30 minutes by ultraviolet (UV) light with a wavelength of 172 nm and an energy of 50 mW/cm² and thus the first connecting region 111 and the second connecting region 112 have the property of conductor. In addition, the heating process can be a laser heating process. Generally, the energy density of the laser beam is greater than 10.0 mJ/cm², preferably greater than 10.710 mJ/cm² and most preferably greater than 14.210 mJ/cm². However, not limited thereto, the energy density of the laser beam can be adjusted depending on the duration of the treatment and the number of the treatment. In another embodiment of the present invention, as shown in FIG. 1D, the first connecting region 111 and the second connecting region 112 can have the property of conductor by irradiating a laser beam with the energy density of greater than 10.0 mJ/cm² thereon. Since the metallic layer 15 can be a mask and light radiation has high collimation, the treatment for making the first connecting region 111 and the second connecting region 112 to have the property of conductor is very precision. Furthermore, the contact resistance of the first connecting region 111 and the second connecting region 112 can be reduced by designing structure or a simple treatment such as a heating treatment or an irradiation process for making the first connecting region 111 and the second connecting region 112 having the property of conductor without the usage of special masks or the requirement of high temperature such as plasma treatment or even the requirement of a vacuum environment.

Again referring to FIG. 1E, a metal is deposited on the substrate 10 for forming a source electrode 17 and a drain electrode 19 thereon, and the source electrode 17 and the drain electrode 19 are electrically connected to the first connecting region 111 and the second connecting region 112, respectively. Therefore, a self-aligned top-gate thin film transistor 1 can be obtained according to an embodiment of the present invention. Preferably, the source electrode 17 and the drain electrode 19 cover the first connecting region 111 and the second connecting region 112, respectively.

According to aforesaid methods, the self-aligned top-gate thin film 1 of the invention is composed of: a substrate 10; an oxide semiconductor layer 11 formed on the substrate 10; a dielectric layer 13 formed on the oxide semiconductor layer 11, allowing the oxide semiconductor layer 11 to be sandwiched between the substrate 10 and the dielectric layer 13; a metal layer 15 formed on the dielectric layer 13, allowing the dielectric layer 13 to be sandwiched between the oxide semiconductor layer 11 and the metal layer 15, wherein the area of the oxide semiconductor layer 11 is larger than the area of the dielectric layer 13 and the area of the metallic layer 15, and the oxide semiconductor layer 11 is defined with a first connecting region 111 and a second connecting region 112 that are not covered by the dielectric layer 13 and the metallic layer 15 thereon respectively, the first connecting region 111 and the second connecting region 112 having the property of conductor; a source electrode 17 formed on the substrate 10 and electrically connected to the first connecting region 111; and a drain electrode 19 formed on the substrate 10 and electrically connected to the second connecting region 112.

In the aforesaid self-aligned top-gate thin film transistor, the oxide semiconductor layer 11 can be made of at least a material selected from the group consisting of indium oxide, zinc oxide, gallium oxide, tin oxide and magnesium oxide. Preferably, the source electrode 17 and the drain electrode 19 cover the first connecting region 111 and the second connecting region 112, respectively.

According to the present invention, the self-aligned top-gate thin film transistor and fabrication method thereof without the process of ion dopants as required by prior art techniques, can reduce the contact resistance of the first connecting region and the second connecting region. Moreover, the number of the defined mask and the production cost can be reduced. Also, a simplified process can be obtained, while the source electrode and drain electrode can be exactly relocated and further increase performance of the device.

The invention has been described using exemplary preferred embodiments. However, it is to be understood that the scope of the invention is not limited to the disclosed arrangements. The scope of the claims, therefore, should be accorded the broadest interpretation, so as to encompass all such modifications and similar arrangements.

What is claimed is:

1. A method for forming a self-aligned top-gate thin film transistor, comprising:
preparing a substrate having sequentially formed thereon an oxide semiconductor layer, a dielectric layer, and a metallic layer, wherein the oxide semiconductor layer is larger in area than the dielectric layer and the metallic layer, and is defined with a first and a second connecting regions that are not covered by the dielectric layer and the metallic layer;
performing a heating process or an ultraviolet irradiation to the first and second connecting regions, with the metallic layer as a mask, to allow the first and second connecting regions to have a property of a conductor; and
forming a source electrode and a drain electrode on the substrate, and electrically connecting the source electrode and the drain electrode to the first and second connecting regions, respectively.

2. The method of claim 1, wherein the oxide semiconductor layer is made of at least a material selected from the group consisting of indium oxide, zinc oxide, gallium oxide, tin oxide and magnesium oxide.

3. The method of claim 1, wherein a wavelength of the ultraviolet radiation is less than 400 nm.

4. The method of claim 1, wherein the heating process is a laser heating process.

5. The method of claim 1, wherein the source electrode and the drain electrode cover the first connecting region and the second connecting region, respectively.

6. A self-aligned top-gate thin film transistor, comprising:
a substrate;
an oxide semiconductor layer formed on the substrate;
a dielectric layer formed on the oxide semiconductor layer, allowing the oxide semiconductor layer to be sandwiched between the substrate and the dielectric layer;
a metal layer formed on the dielectric layer, allowing the dielectric layer to be sandwiched between the oxide semiconductor layer and the metal layer, wherein the oxide semiconductor layer is larger in area than the dielectric layer and the metallic layer, and is defined with a first and a second connecting regions that are not covered by the dielectric layer and the metallic layer, the first and second connecting regions having a property of a conductor;
a source electrode formed on the substrate and electrically connected to the first connecting region; and
a drain electrode formed on the substrate and electrically connected to the second connecting region.

7. The self-aligned top-gate thin film transistor of claim 6, wherein the oxide semiconductor layer is made of at least a material selected from the group consisting of indium oxide, zinc oxide, gallium oxide, tin oxide and magnesium oxide.

8. The self-aligned top-gate thin film transistor of claim 6, wherein the source electrode and the drain electrode cover the first connecting region and the second connecting region, respectively.
